(19) United States
(12) Patent Application Publication
(10) Pub. No.: US 2012/0232814 A1
(43) Pub. Date: Sep. 13, 2012

(54) FREQUENCY-SAMPLING CIRCUIT AND METHOD FOR HEALTH PROGNOSTICS

(75) Inventors: James P. Hofmeister, Tombstone, AZ (US); Douglas L. Goodman, Tucson, AZ (US); William J. Gleeson, III, Tucson, AZ (US)

(73) Assignee: Ridgetop Group, Inc.

(21) Appl. No.: 13/407,341

(22) Filed: Feb. 28, 2012

Related U.S. Application Data
(60) Provisional application No. 61/464,538, filed on Mar. 7, 2011.

(51) Int. Cl. G06F 19/00

(52) U.S. Cl. 702/60

(57) ABSTRACT

The present invention provides a frequency-sampling circuit and method for characterizing a health condition of a test unit attached to a power supply. The frequency-sampling circuit is connected externally to the test unit. The circuit comprises an inductor and a capacitor connected in series at an output. When switched, the circuit resonates with an AC loop current to produce a damped-frequency response at the output. Frequency measurements of this response are processed to generate SoH or RUL estimates for the test unit. The voltages applied within the frequency-sampling circuit are limited, which in turn limits the AC loop current to avoid loading the power supply. Incorporating the inductance and capacitance with in the frequency-sampling circuit allows the circuit to be configured for different classes of test units having a wide range of characteristic impedances.

### CROSS-REFERENCE TO RELATED APPLICATIONS

This application claims benefit of priority under 35 U.S.C. 119(e) to U.S. Provisional Application No. 61/464,538 entitled “Attached frequency-sampling circuit to produce a prognostic signal for a device or electronic assembly” and filed on Mar. 7, 2011, the entire contents of which are incorporated by reference.

### BACKGROUND OF THE INVENTION

1. Field of the Invention

This invention relates to prognostic health monitoring of a “test unit” such as an electronic device or assembly to detect fault-to-failure progression (FFP) signatures to assess the state of health (SoH) of the test unit and the remaining useful life (RUL) of the test unit, and more particularly to a circuit and method for generating a frequency-damped response without loading the test unit or its power supply and generating resonant-frequency measurements as indicative of a health condition of the characteristic impedance as a proxy for a health condition of the test unit. Changes in the resonant frequency of the response and the rate of change of the resonant frequency may be used to create the FFP signatures to estimate SoH and RUL of the test unit.

2. Description of the Related Art

Prognostic methods are used to improve the reliability of deployed systems by looking at components that have high failure rates and critical impact on performance within the systems. Detectors, or sensors, monitor these systems and look for failure precursors that indicate the high-failure rate components have entered a wear-out mode and are degrading toward failure. By knowing the progression of failure dynamics for a test unit (e.g. an electronic device or assembly), an accurate prediction of time to failure (TTF) or remaining useful life (RUL) can be made and an appropriate maintenance action, such as remove and replace the device or assembly, can be initiated to avoid system failure during a time of operation. Fault-to-failure progression (FFP) signature detection is a method or capability to detect and report a precursor-to-failure or incipient fault condition of a component device or assembly containing the component device. Such detection is the basis for a notification capability to provide early warning of degradation and eventual failure.

A direct approach is to place sensors at the board level at each node of each component having a significant rate of failure: faults are detected and tracked. In many cases, there are interdependencies in these tracking measurements that require an expert system to produce RUL estimates. with greater accuracy. This direct approach is invasive because it requires internal access to components within the system: adding sensors inside the power supply imposes an additional reliability load. Manufacturers of power supplies (e.g. switched-mode, rectifying, converter) can be reluctant to enable prognostics on their supplies, believing that the benefits of this capability do not justify the cost and/or that these benefits do not outweigh the additional reliability burden. Currently, this direct approach to prognostics has not been adopted in many applications. A non-invasive approach uses external access methods, such as using an output voltage terminal, to attach electronic equipment to measure values, inject stimuli and sense responses.

A variety of non-invasive techniques exist for identify failure precursors in switch mode power supplies (SMPS). Lahyani, “Failure Prediction of Electrolytic Capacitors of a Switch Mode Power Supply, IEEE Transactions on Power Electronics, Vol 13, No. 6, November 1998 monitors the ripple voltage at the output terminals of the power supply. The precursor to failure is an increase in ripple voltage caused by increasing degradation of the supply's output capacitor as it fails. U.S. Pat. No. 4,245,289 to Mineck measures the duly cycle modulated by an integrated circuit (IC) component that is responsible for switch timing. Mineck is based on the premise that electronic components consume more power as they begin to fail. The precursor-to-failure utilized in Mineck is an increase in duty cycle.

U.S. Pat. No. 7,619,908 to Hofmeister et al describes a system that includes a current injection device in electrical communication with a switch mode power supply. The current injection device is positioned to alter the initial, non-zero load current when activated. A prognostic control is in communication with the current injection device, controlling activation of the current injection device. A detector is positioned to receive an output signal from the switch mode power supply and is able to count cycles in a sinusoidal wave within the output signal. An output device is in communication with the frequency detector. The output device outputs a result of the counted cycles, which are indicative of damage to and a remaining useful life of the switch mode power supply.

As shown in FIG. 6 of the U.S. Pat. No. 7,619,908, a current injection device 134 includes an injection inverter 136, an injection switch 138 having a P-channel power MOSFET and a injection load resistor 140. The current injection device 134 has a first terminal 142 that is connected to a voltage output bus 104 at first connection point 106. A second terminal 144 is connected to terminal 115A or terminal 115B (shown in FIG. 5). When an input 146, connected to the injection inverter 136, is positive, the injection inverter 136 turns on the injection switch 138 to connect the injection load resistor 140 to the voltage output bus 104 at first connection point 106. The result of the positive input 146 is an abrupt change in the load current of the SMPS (such as the prior art SMPS shown in FIG. 1), which results in a damped ringing such as that shown in FIG. 3. The current injection device 134 is able to inject an abrupt current change of known duration and it injects a current change of known amplitude, which is the output voltage at the voltage output bus 104 divided by the value of the injection load resistor 140.

### SUMMARY OF THE INVENTION

The following is a summary of the invention in order to provide a basic understanding of some aspects of the invention. This summary is not intended to identify key or critical elements of the invention or to delineate the scope of the invention. Its sole purpose is to present some concepts of the invention in a simplified form as a prelude to the more detailed description and the defining claims that are presented later.

The present invention provides a circuit and method for characterizing a health condition of a test unit (e.g. an electronic device or assembly) having characteristic impedance between external signal and reference connections. In different embodiments the circuit and method can be used to characterize different classes of test units, powered and unpowered, having a wide range of characteristic impedance. In different embodiments the circuit and method can characterize the health conditions at low injection currents and applied voltages with low wattage rated components.

This is accomplished by connecting a frequency-sampling circuit between the test unit's external signal and reference connections. A power supply, either attached to the test unit in-situ or as part of the test procedure, supplies power to the test unit. The frequency-sampling circuit includes a capacitor and an inductor connected at an output. The circuit is switched, either physically or electrically, between non-sampling and sampling topologies to generate a damped-frequency response at the output. Switching the circuit to the sampling topology changes a DC voltage potential at the output causing a tuned circuit of the series-connected inductor, capacitor and test unit impedance to resonant inducing an AC loop current at the resonant frequency producing the damped-frequency response. A voltage circuit establishes a predetermined non-zero DC voltage potential (“predetermined potential”) that limits the change in the DC voltage potential at the output, which in turn limits the AC loop current thereby limiting the load placed on the test unit or its power supply. The damped-frequency response is processed to generate a resonant-frequency measurement. The circuit may be switched at a sampling rate to generate a sequence of resonant-frequency measurements. These measurements, changes in these measurements or the rate of change of the measurements are processed to generate an indicator of a health condition of the characteristic impedance as a proxy for a health condition of the test unit.

In an embodiment, a processing unit processes the damped-frequency response to generate a frequency measurement and create a prognostic signal representing a time-stamped FFP signature (e.g. frequency measurement, normalized frequency measurement, or change in frequency). The prognostic signal is passed to a prognostic health monitor to generate the SoH or RUL as the indicator of the health condition of the test unit.

In an embodiment, the voltage circuit establishes the predetermined potential at a level that is less than 2% of an input voltage potential between the signal and reference connections. The voltage circuit may, for example, comprise a resistive voltage-divider or a current-limited DC supply. The predetermined potential in turn limits the magnitude of the AC loop current to be less than a designed-for percentage of the power supply's reserve power for handling power and load fluctuations. This designed-for percent may be, for example, suitably 5% or preferably 1% of the total power supply current.

In an embodiment, the frequency-sampling circuit comprises a series connection of the capacitor, a switch and the inductor between the signal and reference connections. In the non-sampling topology, the switch is open disconnecting the inductor from the tuned circuit. The DC voltage potential at the output is offset from either the reference potential or the signal potential by the predetermined potential. A controller closes the switch thereby physically switching the circuit to its sampling topology. Closing the switch instantaneously shorts the output through the inductor to either the reference or signal potential inducing the AC loop current to flow through the tuned circuit and resonate to produce the damped-frequency response at the output. The predetermined potential limits the change in the DC voltage potential at the output when the switch is closed, and, in turn, limits the magnitude of the AC loop current.

In an embodiment, the frequency-sampling circuit comprises a series connection of the capacitor and the inductor between the signal and reference connections. A power supply generates a time-varying voltage signal to electrically switch the frequency-sampling circuit between its non-sampling and sampling topologies. In the non-sampling topology, the output is shorted through the inductor and resides at either the signal or reference potential. When the time-varying signal changes state it electrically switches the circuit to its sampling topology. The signal changes the DC voltage potential at the output thereby applying a voltage across the inductor inducing the AC loop current to flow through the tuned circuit and resonate to produce the damped-frequency response at the output. The predetermined potential limits the change in the DC voltage potential at the output when the topology is switched, and, in turn, limits the magnitude of the AC loop current.

These and other features and advantages of the invention will be apparent to those skilled in the art from the following detailed description of preferred embodiments, taken together with the accompanying drawings, in which:

### BRIEF DESCRIPTION OF THE DRAWINGS

FIG. 1 is a simplified block and schematic diagram of a first embodiment frequency-sampling circuit attached to a test unit;

FIG. 2 is a plot of loop current that flows through a tuned circuit formed by the series connection of the test unit's impedance and the circuit's capacitance and inductance

FIG. 3 is a plot of the frequency-damped voltage response produced at an output between the circuit's capacitance and inductance;

FIG. 4 is a simplified block and schematic diagram of a second embodiment of a frequency-sampling circuit attached to a test unit;

FIG. 5 is a plot of the frequency-damped voltage response;

FIG. 6 is a simplified block and schematic diagram of a third embodiment of a frequency-sampling circuit attached to a test unit;

FIG. 7 is a plot of the frequency-damped voltage response;

FIG. 8 is a simplified block and schematic diagram of a fourth embodiment of a frequency-sampling circuit attached to an unpowered test unit;

FIG. 9 is a plot of the frequency-damped voltage response at the input of the test unit;

FIG. 10 is a plot of the frequency-damped voltage response at the input on a finer time-scale revealing harmonic distortions caused by the test unit;

FIG. 11 is a plot of the frequency-damped voltage response at the output of the test unit;

FIG. 12 is a plot of frequency measurements of the frequency-damped voltage response sampled over time that define an FFP signature;

FIG. 13 is a line plot of remaining useful life (RUL) estimates based on the rate of change of the frequency measurements; and

FIG. 14 is a line plot of state-of-health estimates based on the FFP signature and RUL estimates.

### DETAILED DESCRIPTION OF THE INVENTION

The present invention provides a frequency-sampling circuit and method for characterizing a health condition of a test unit, which may be an electronic device or assembly. The frequency-sampling circuit is connected externally to the test unit. The frequency-sampling circuit may remain in place to provide “in-situ” measurements or may be periodically connected and disconnected to provide measurements. The circuit comprises an inductor and a capacitor connected in series at a circuit output. When switched, physically or electronically, the circuit resonates to produce a damped-frequency response at the output. Measurements of the resonant frequency of this response are processed to generate SoH or RUL estimates for the test unit. A voltage circuit establishes a predetermined non-zero DC voltage potential (“predetermined potential”) that limits the change in the DC voltage potential at the output and limits the AC loop currents. The “predetermined potential” is non-zero with respect to the reference or signal potential. Incorporating the inductance and capacitance within the frequency-sampling circuit allows the circuit to be configured for different classes of test units having a wide range of characteristic impedances while simplifying and improving the measurement of the resonant frequency. Establishing the predetermined potential at levels much lower than the input voltage potential limits the applied voltages, reducing stress on electrical components, and in turn limits the AC loop currents to be within a designed-for percentage of the supply's reserve power for handling power and load fluctuations and to not exceed the rated load of the test unit. The test unit, which is typically a fielded electronic device or assembly, may remain fully operational while the frequency-sampling circuit is attached and in fact operating in its sampling topology.

The test unit's characteristic impedance may be an input impedance, an intermediate impedance or an output impedance. In some cases, the test unit may have external connections for multiple, differing impedances. In the latter case, different frequency-sampling circuits may be connected to input and output terminals, for example, to monitor health conditions at the input and output. The test unit's characteristic impedance may be capacitive only, inductive only or a combination of inductive and capacitive. The test unit may be part of a class of units having specified nominal characteristic impedance to which the frequency-sampling circuit is designed. The topology of the frequency-sampling circuit is such that the circuit may be configured (by adjusting the inductance and capacitance) for different unit classes having widely ranging impedance.

The test unit may be powered or unpowered: powered test units either include a power supply or are attached in-situ to a power supply. Examples of powered test units include but are not limited to a switch mode power supply (SMPS), rectifying power supplies, converter power supplies, an optical isolator within a SMPS, a wire heating element connected in-situ to a power supply, and an output circuit of signal-transmitter. Unpowered test units require the test system provide a power supply. Examples of unpowered test units include but are not limited to a wire, a heating element, and a signal-transmission cable that are not connected in-situ to a power supply. The topology of the frequency-sampling circuit may be configured for either power or unpowered test units.

Power supplies will typically have reserve power for handling power and load fluctuations. The reserve power may, for example, represent 10-20% of the total available power. Of this perhaps 10-25% of the reserve power (1-5% of the total power) may be allocated for prognostic purposes. If the induced AC loop currents exceed this designed-for percentage of the reserve power (or total power), the frequency-sampling circuit may interfere with the supply's ability to source current. Test units may also have rated maximum voltages or current levels. The frequency-sampling circuit and particularly the voltage circuit are configured to establish a “predetermined potential” so that the AC loop currents are less than the designed-for percentage of reserve power for the power supply and the rated maximum current level of the test unit. The predetermined potential is typically 100 mV or less.

The test unit impedance may be modeled as a series connection of an inductor L_{D} and a capacitor C_{D}. The frequency-sampling circuit may be modeled as a series connection of an inductor L_{S} and a capacitor C_{S}. Switching to the sampling topology creates a tuned circuit of a series connection of the test unit impedance and circuit inductor and capacitor. The effective capacitance of the two series capacitors is modeled by Ceff=(C_{D}×C_{S})/(C_{D}+C_{S}). The effective inductance of the series inductors is modeled by Leff=L_{D}+L_{S}. The resonant frequency ω_{R} of the tuned circuit is ω_{R}=(1/(SQRT(Leff×Ceff)). The damped-frequency response V_{R} can be modeled as V_{R}=V_{DC}+A_{R}×COS(ω_{R}+φ)×EXP(−t/τ) where V_{DC} is the DC voltage potential at the output of the frequency-sampling circuit, A_{R} is the amplitude, ω_{R} is the resonant frequency (in radians), φ is the phase shift of the frequency response, t is the time relative to start of the damped-frequency response as determined by trailing edge of a switching voltage, τ is a dampening time constant, and EXP(−t/τ) determines the rate of damping. The dampening time constant τ=Reff×Ceff where Reff is the effective series resistance of the test unit and frequency-sampling circuit. The maximum AC loop current through the circuit inductor L_{S} is modeled as I_{MAX}=V_{MAX}/X_{L}, where X_{L} is the impedance of the inductor and V_{MAX} is the maximum voltage across the inductor. Establishment of a small predetermined non-zero DC voltage potential at the output, limits the maximum voltage, which in turn limits the maximum AC loop current.

The resonant-frequency measurements, changes in these measurements or the rate of change of the measurements are processed to generate an indicator of a health condition of the characteristic impedance as a proxy for a health condition of the test unit. For example, if the output capacitance of a test unit is degrading this is a direct indicator that the health of the test unit is failing. For example, a SMPS includes a filter circuit with an output capacitance. Degradation of the output capacitance can be used as a “proxy” for degradation of the filter circuit, hence the SMPS. As the health condition of a test unit degrades, its capacitance, for example becomes smaller causing the resonant frequency to increase. In an embodiment, a processing unit processes the damped-frequency response to generate a frequency measurement and create a prognostic signal representing a time-stamped FFP signature (e.g. frequency measurement, normalized frequency measurement, or change in frequency). The prognostic signal is passed to a prognostic health monitor to generate the SoH or RUL as the indicator of the health condition of the test unit.

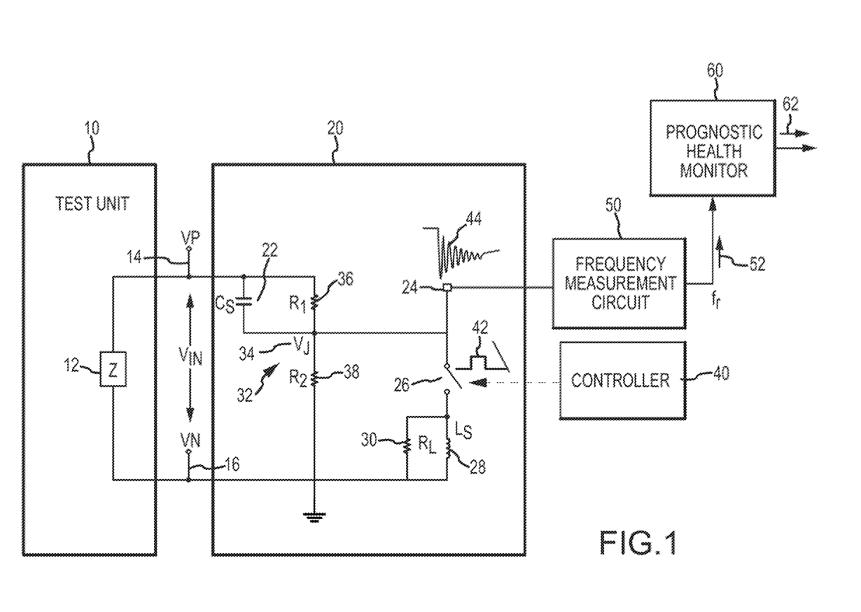

Referring now to FIGS. 1-3, a test unit 10 comprises an impedance Z 12 (e.g. a capacitance and/or inductance) between an external signal connection 14 and an external reference connection 16. Test unit 10 is attached to a power supply (not shown) that establishes a signal potential VP at signal connection 14 and a reference potential VN at reference connection 16 that provide an input voltage V_{IN} between the connections. For simplicity the reference potential may be assumed to be at 0 volts. In some instances, a load may be connected between the signal and reference connections. The power supply and test unit may drive the load and remain fully operational. The input voltage V_{IN} may be a few volts to kilovolts. In this example, the power supply is rated at 3.5 V and 50 A total current.

In a first embodiment, a frequency-sampling circuit (FSC) 20 is connected between external signal connection 14 and external reference connection 16. The circuit comprises a capacitor C_{S} 22 connected between signal connection 14 and an output 24, a switch 26 such as a MOSFET or mechanical relay switch connected between output 24 and an inductor L_{S} 28, which is connected to reference connection 16. A resistor R_{L} 30 is suitably connected in parallel with inductor L_{S} 28. The circuit further comprises a voltage circuit 32 that establishes a predetermined non-zero DC voltage potential V_{J} 34 (“predetermined potential”) at output 24. In this example, voltage circuit 32 is a resistive voltage-divider that includes a first resistor R1 36 connected between signal connection 14 and output 24 and a second resistor R2 38 connected between output 24 and reference connection 16. R1>>R2 so that V_{J} is <<V_{IN}. V_{J} is suitably less than 2% of Vin, which is typically a few volts to kilovolts and V_{J} is typically less than a few hundred millivolts.

A controller 40 switches a control voltage 42 to open and close switch 26 to switch FSC 20 between a non-sampling topology in which inductor 28 is disconnected and a sampling topology in which inductor 28 is connected to produce a damped-frequency response 44 at output 24; the damped-frequency response 44 being the AC component of the voltage potential at output 24. Controller 40 controls the sampling rate (i.e. how often a pulse is issued to close the switch) and the sampling period (i.e. how long the switch is closed). The sampling rate may depend on multiple factors including but not limited to how fast a class of test units tends to degrade, customer requirements as to accuracy of SoH and RUL estimates and the SoH and RUL algorithms employed. The sampling period is largely determined by the dampening time constant.

A frequency-measurement circuit 50 coupled to output 24 calculates and outputs a resonant-frequency measurement fᵣ 52 of damped-frequency response 44. Frequency-measurement circuit 50 may suitably comprise an amplifier to amplify response 44, an analog-to-digital converter (ADC) that samples the response to generate digital samples and a processing unit that determines an estimate of the resonant frequency. The circuit may create a prognostic signal as measurement 52 representing a time-stamped FFP signature (e.g. frequency measurement, normalized frequency measurement, or change in frequency). An advantage of the frequency-sampling circuit is that by controlling the predetermined potential the circuit can match the amplitude of the damped-frequency to the ADC to improve SNR (signal-to-noise-ratio). Additionally, the circuit can control the resonant frequency so that it lies with a range for which measurement is simpler and more accurate.

A prognostic health monitor 60 processes frequency measurement 52 to generate an indicator 62 of a health condition of the characteristic impedance as a proxy for a health condition of the test unit. The monitor may process changes in frequency response to generate the SoH or the rate of change in frequency to generate the RUL. The monitor may implement any method to convert time-stamped FFP values into estimates of SoH and/or RUL.

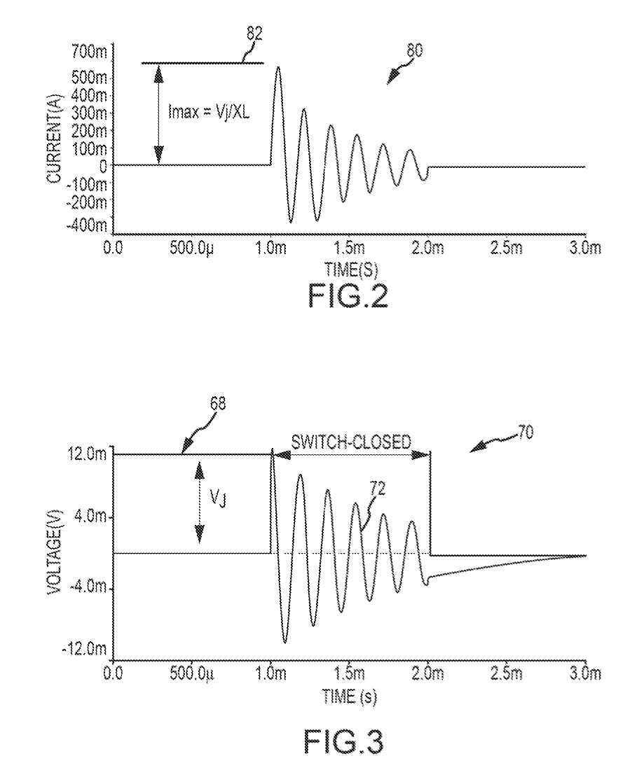

In a steady-state condition in the non-sampling topology, inductor 28 is disconnected. A small DC current flows through voltage divider 32 to set a DC component 68 of a voltage 70 at output 24 at the predetermined potential V_{J} 34. As shown in FIG. 3, DC component 68 of voltage 70 is held at 12 mv although Vin provided by the power supply is 3.38 V. As shown in FIG. 2, the initial level of a current 80 through inductor 28 is zero. Capacitor 22 is fully charged.

Closing switch 26, switches the frequency-sampling circuit from the non-sampling topology to the sampling topology to simultaneously create a tuned circuit comprising a series connection of the test unit's characteristic impedance Z and the circuit's inductor 28 and capacitor 22 and to change the voltage potential 70 at output 24 causing the tuned circuit to resonate and a non-zero AC loop current 80 to flow in the tuned circuit producing damped-frequency response 44 at the circuit's output. Closing the switch at t=1.0 ms instantaneously shorts output 24 through inductor 28 to the reference potential causing voltage potential) 70 to change from the predetermined potential V_{J} to zero volts. An AC component 72 of voltage potential 70 goes negative as the tuned circuit starts to resonate, oscillates about the reference potential and dampens as energy is absorbed by the circuit resistance to form damped-frequency response 44. The maximum amplitude of the AC component 72 of voltage potential 70 is limited by the predetermined potential V_{J}. Eventually the AC component will dampen out and voltage potential 70 will return to a steady-state condition of 0 volts because inductor 28 is a short at DC. Current 80 resonates to provide an AC loop current in the tuned circuit. The maximum amplitude 82 or the AC loop current is limited by the maximum amplitude (V_{J}) of the AC component of voltage potential 70 divided by is the impedance X_{L} of the inductor L_{S}. In this case, the maximum amplitude of AC loop current 80 is approximately 600 milliamps. The attached power supply had a total current capability of 50 Amps of which 10% is reserved. The 600 milliamps is less than 15% of the reserve and less than 1.5% of the total current capability of the supply.

Opening the switch at t=2.0 ms disconnects inductor 28 from the tuned circuit. Resistor 30 is a bleed resistor that drains the energy stored on inductor 28 and prevents arcing between inductor 28 and capacitor 22. Capacitor 22 charges or discharges (as determined by voltage 72 when the switch is opened) through resistor 30 to re-establish the predetermined potential V_{J} at output 24.

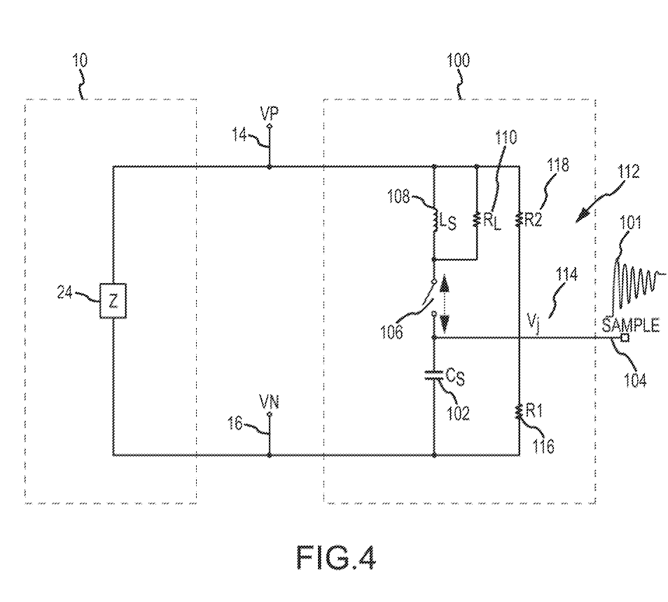

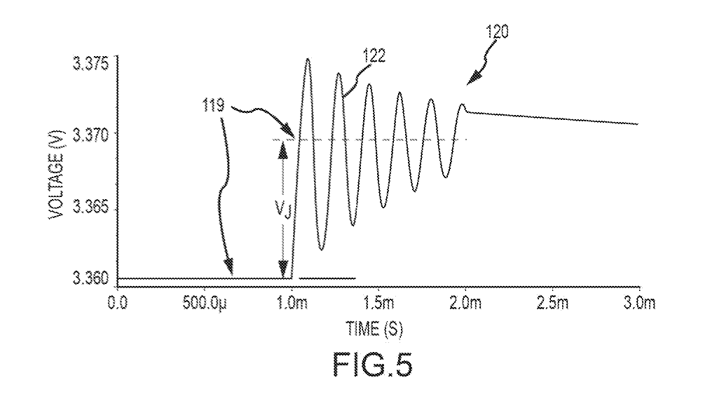

Referring now to FIGS. 4-5, in a second embodiment a frequency-sampling circuit 100 is connected between external signal connection 14 and external reference connection 16. Frequency-sampling circuit 100 is a mirror image of frequency-sampling circuit 20; reversing the connections to the external signal connection 14 and external reference connection 16. Assuming identical values of capacitance and inductance, the measured resonant frequency of the damped-frequency response 101 is the same for both embodiments.

Circuit 100 comprises a capacitor C_{S} 102 connected between reference connection 16 and an output 104, a switch 106 such as a MOSFET or mechanical relay switch connected between output 104 and an inductor L_{S} 108, which is connected to signal connection 14. A resistor R_{L} 110 is suitably connected in parallel with inductor L_{S} 108. The circuit further comprises a voltage circuit 112 that establishes a predetermined non-zero DC voltage potential V_{J} 114 at output 104. In this example, voltage circuit 112 is a resistive voltage-divider that includes a first resistor R1 116 connected between reference connection 16 and output 104 and a second resistor R2 118 connected between output 104 and signal connection 14. R1>>R2 so that V_{J} (referenced to signal potential VP) is <<V_{IN}. V_{J} is suitably greater than 98% of V_{IN} of 3.37 V supplied by the power supply to achieve a differential of less than 2% of V_{IN}. V_{IN} is typically a few volts to kilovolts and V_{J} is typically less than a few hundred millivolts less than V_{IN}.

As shown in FIG. 5, a DC component 119 of voltage potential 120 at output 104 is at 3.36 volts. When switch 106 is closed, output 104 is instantaneously shorted (on the order of tens of nanoseconds) through inductor 108 to the signal potential causing voltage potential 120 to change and induce an AC loop current to flow through the tuned circuit. In this case, the DC component 119 of voltage potential 120 shifts to a higher voltage potential at the signal potential. An AC component 122 of voltage potential 120 oscillates about the signal potential with maximum amplitude limited by the predetermined potential to form the damped-frequency response 101. Eventually AC component would dampen out and voltage potential 120 would reach a steady-state condition at the signal potential because inductor 108 is a short to DC. When switch 106 is opened, the voltage potential 120 at output 104 discharges or charges from the signal potential to a lower potential determined by the predetermined potential V_{J} offset from the signal voltage.

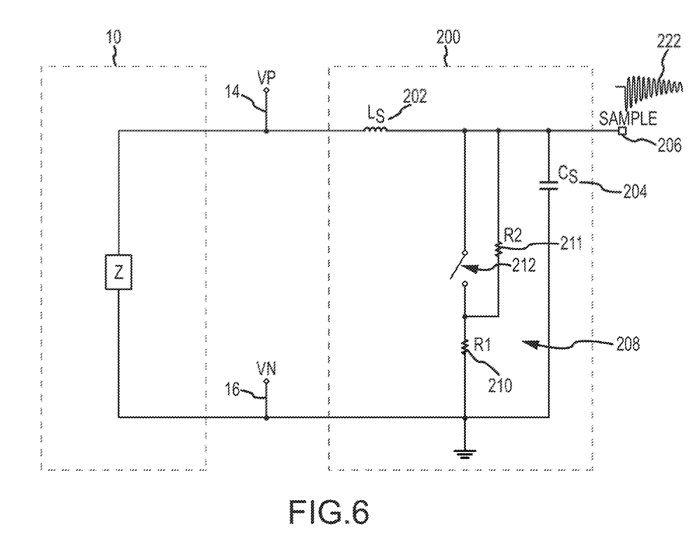

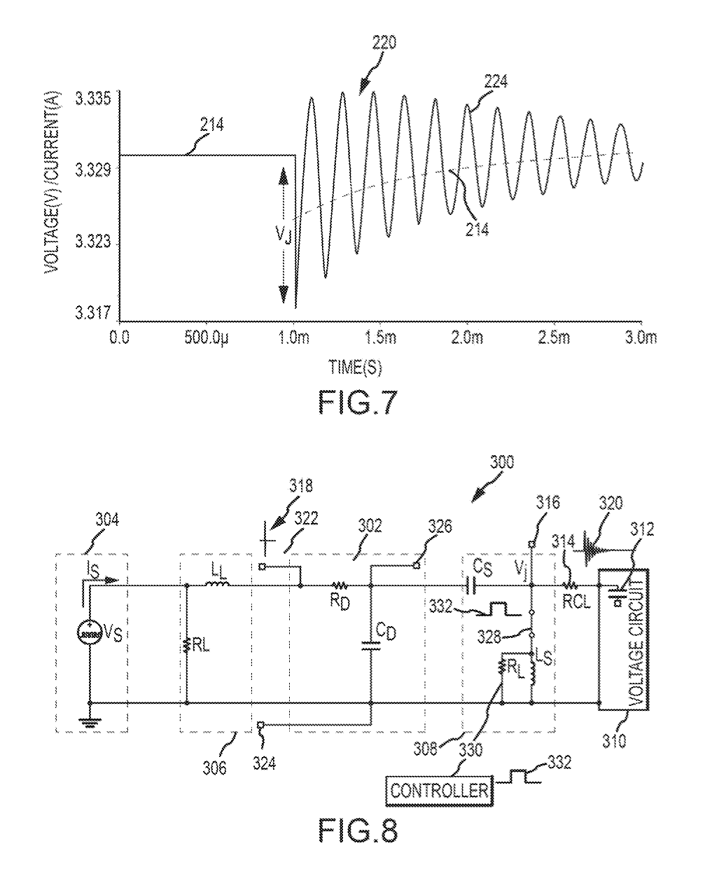

Referring now to FIGS. 6-7, in a third embodiment, a frequency-sampling circuit 200 is connected between external signal connection 14 and external reference connection 16. In this embodiment, the inductor is not switched in and out of the tuned circuit. Instead a resistor is switched to switch the topology and cause the circuit to resonant. Although the switching mechanism is different, assuming identical values of capacitance and inductance, the measured resonant frequency of the damped-frequency response is the same as for the previous embodiments. This approach does have a small DC current that flows through the inductor L_{S} 202 during steady-state.

Frequency-sampling circuit 200 comprises a series connection of an inductor L_{S} 202 and a capacitor C_{S} 204 connected between signal connection 14 and reference connection 16. An output 206 is at the junction connection of the inductor and capacitor. A voltage-divider 208 is connected between the series inductor L_{S} 202 and the reference connection 16 to establish the predetermined potential V_{J}. The divider includes a first resistor R1 210 connected to the reference connection and a second resistor R2 211 connected to the inductor L_{S} 202 where R1>>R2. A switch 212 is connected in parallel to resistor R2 211 between inductor L_{S} 202 and the top of resister R1.

As shown in FIG. 7, in steady-state conditions switch 212 is open and a DC component 214 of a voltage potential 220 at output 206 is at the signal potential (ignoring a small voltage drop across inductor 202). The voltage at the top of resister R1 is offset from the signal potential by the predetermined potential V_{J}. When switch 212 is closed, resister R2 is shorted instantaneously shorting output 206 to the voltage potential at the top of resister R1. This in turn causes an abrupt increase in current to flow through resister R1 causing the tuned circuit of test unit impedance Z and circuit inductance and capacitance L_{S} and C_{S} to resonant and produce a damped-frequency response 222 (FIG. 6) as an AC component 224 (FIG. 7) of voltage potential 220. The DC component 214 of the voltage potential is not a steady-state voltage but rather it exponentially increases to the non-sampling DC voltage level. AC component 224 of voltage potential 220 oscillates about DC component 214 and eventually dampens out. As before, the predetermined potential V_{J} limits the maximum amplitude of the AC component 224 of voltage potential 220, which in turn limits the maximum amplitude of the AC loop current that flows through the tuned circuit. When switch 212 is opened, the voltage potential 220 at output 206 becomes a steady-state DC at the non-sampling DC voltage level.

Referring now to FIGS. 8-11, in a fourth embodiment, a frequency-sampling circuit 300 comprising sub-circuits 306 and 308 is depicted for use with a test unit 302 such as a shielded wire that is not attached to a built-in power supply. In this case, a power supply 304, either a DC supply or an AC signal generator, is attached to the test unit as part of the prognostic health monitoring procedure to supply a source voltage V_{S} and a total source current I_{S}. Test unit 302 may be modeled as comprising an equivalent resistor R_{D} and an output capacitor C_{D}. In both cases, the frequency-sampling circuit typically comprises an input sub-circuit 306 suitably comprising a load resistor R_{L} and a load inductor L_{L} connected between the power supply and the test unit to provide isolation and protect the test unit from an in rush of current from the supply and an output sub-circuit 308 to produce the damped-frequency response. If used with a DC supply the output sub-circuit may be identical to the frequency-sampling circuits previously described in which the attached power supply is built-in. If used with an AC signal generator, the supply's time-varying voltage signal may be used to electrically switch the topology of the output segment thereby obviating the need for a physical switch. In this embodiment, the voltage circuit 310 is depicted as an external current-limited DC source such as a battery 312 and current-limiting resistor 314 that establishes the predetermined potential V_{J} at the output 316. In this embodiment, damped-frequency responses 318 and 320 are generated and measured between both an external input signal connection 322 and an external reference connection 324 and output 316 and reference connections 324, respectively.

Output sub-circuit 308 is connected between external output signal connection 326 and external reference connection 324. Output sub-circuit 308 comprises a capacitor C_{S} connected between signal connection 326 and output 316 and an inductor L_{S} connected between output 316 and reference connection 324. If power supply 304 is a DC supply, a switch 328 is connected between output 316 and inductor L_{S}. A resistor R_{L} is suitably connected in parallel with inductor L_{S}. The output sub-circuit further comprises a voltage circuit 310 that establishes predetermined non-zero DC voltage potential V_{J} at output 316. In this example, voltage circuit 310 is a current-limited DC source that includes battery 312 and a current limiting resistor RCL 314. The value of the current-limiting resistor RCL 314 is designed to ensure that when the DC voltage is reduced instantaneously to zero, the maximum current from the voltage circuit to the output is less than the designed-for-maximum value of the AC loop current—some voltage circuits have a built-in current-limiting capability, and thereby a current-limiting resistor is not required. V_{J} is suitably less than 2% of the input voltage V_{IN} supplied by power supply 304. V_{IN} is typically a few volts to kilovolts and V_{J} is typically less than a few hundred millivolts.

If power supply 304 is a DC supply, a controller 330 switches a control voltage 332 to open and close switch 328 to switch output sub-circuit 308 between a non-sampling topology in which inductor L_{S} is disconnected and a sampling topology in which inductor L_{S} is connected to produce damped-frequency responses 318 and 320. Controller 330 controls the sampling rate (i.e. how often a pulse is issued to close the switch) and the sampling period (i.e. how long the switch is closed). The sampling rate may depend on multiple factors including but not limited to how fast a class of test units tends to degrade, customer requirements as to accuracy of SoH and RUL estimates, and the SoH and RUL algorithms employed. The sampling period is largely determined by the dampening time constant.

If power supply 304 is a signal generator that supplies source V_{S} as a time-varying signal such as a pulse sequence, the signal electrically switches the output segment between its non-sampling and sampling topologies. In the non-sampling topology, output 316 is shorted through inductor L_{S} and resides at the reference potential (e.g. 0 V). When the time-varying signal changes state it electrically switches the circuit to its sampling topology. The signal changes the DC voltage potential at the output and thereby changes the voltage across inductor L_{S}, which causes the AC loop current to flow through the tuned circuit and resonate to produce the damped-frequency response 320 at the output. The predetermined potential V_{J} limits the amplitude of AC component of voltage potential at the output when the topology is switched, and, in turn, limits the magnitude of the AC loop current.

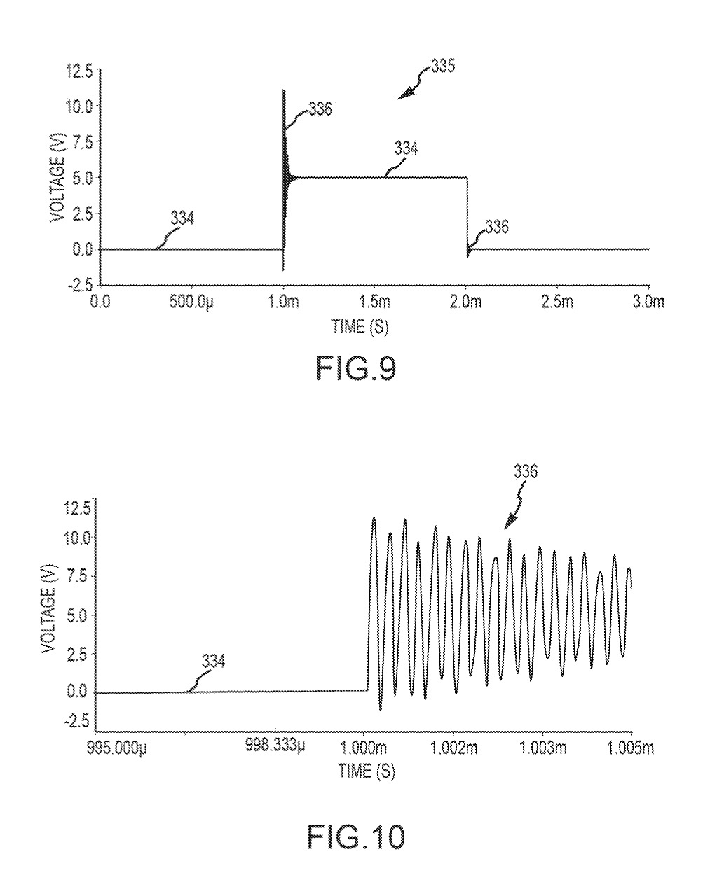

The damped-frequency response 318 measured between the external input signal connection 322 and reference connection 324 in FIG. 8 is depicted on different time scales in FIG. 9 and FIG. 10. In this example, the supply voltage V_{S} switches from 0 to 5 V. As shown in FIG. 9, a DC component 334 of a voltage potential 335 is a steady-state 0 V. The DC component 334 switches with supply voltage V_{S} to 5 V and back to 0 V. Switching induces an AC component 336 that forms damped-frequency response 318 at both the leading and trailing edges of the pulse. On the leading edge the amplitude of the AC component 336 will oscillate about 5 V with a maximum amplitude change of approximately 7.5 plus and minus until dampening out. As shown in FIG. 10, the AC component 336 reveals harmonics distortions caused by the test unit.

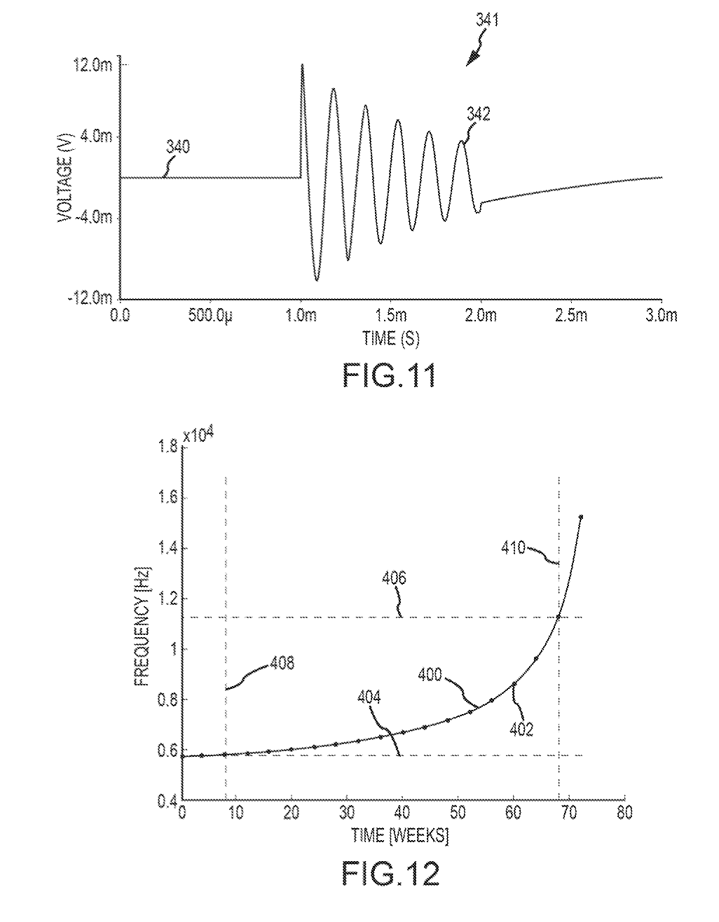

The damped-frequency response 320 measured between the external input signal connection 326 and reference connection 324 in FIG. 8 is depicted in FIG. 11. A DC component 340 of a voltage potential 341 resides a 0 V steady-state. Switching induces an AC component 342 of the voltage potential, which forms damped-frequency response 320, which in turn induces the AC loop current to flow in the tuned circuit. The amplitude of the AC component is limited to 12 mv by the predetermined potential set by the current-limited DC source, which in turn limits the amplitude of the AC loop current.

The resonant-frequency measurements, changes in these measurements or the rate of change of the measurements are processed to generate an indicator of a health condition of the characteristic impedance as a proxy for a health condition of the test unit. As the health condition of a test unit degrades, its capacitance, for example becomes smaller causing the resonant frequency to increase. In an embodiment, a processing unit processes the damped-frequency response to generate a frequency measurement and create a prognostic signal representing a time-stamped FFP signature (e.g. frequency measurement, normalized frequency measurement, or change in frequency). The prognostic signal is passed to a prognostic health monitor to generate the SoH or RUL as the indicator of the health condition of the test unit.

FIG. 12 shows a line plot 400 of resonant-frequency measurements 402 of the damped-frequency response 44 for the system of FIG. 1 in which the frequency increases from less than 6,000 Hz at time zero for no degradation in test unit impedance Z 12 to over 15,000 Hz. as the impedance degrades at a constant rate. The FFP signature model has a defined floor threshold, onset of damage, indicated by the dashed, lower horizontal plot line 404 and defined ceiling threshold, failure, indicated by the dashed, upper horizontal plot line 406. Before time 408, the measured frequency is below the defined floor threshold, and consequently the test unit is deemed 100 percent healthy; at time 408 (8 weeks), the measured frequency equals the defined floor threshold 404: onset of detectable damage; at time 410 (68 weeks), the measured frequency equals the defined ceiling threshold 406: damage progression has caused sufficient reduction in the test unit output impedance to declare the test unit as electrically failed. The y-axis (amplitude) is the measured frequency and the x-axis (time) is the time of the frequency measurements. It is understood the FFP signature curve 400 can be normalized to a ratio value by dividing frequency measurements by a base value of frequency such as the defined floor or ceiling values of frequency.

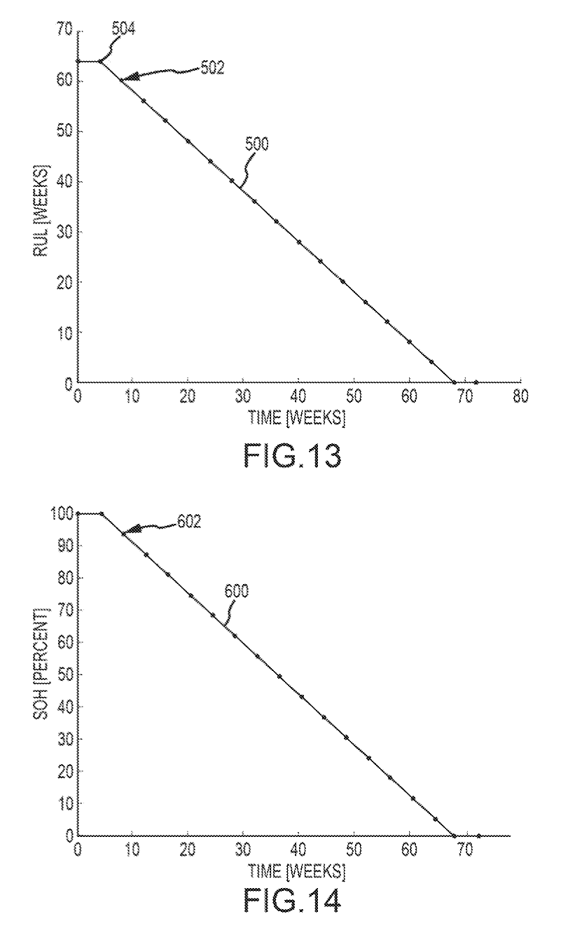

FIG. 13 is a line plot 500 of RUL (remaining, useful life) estimates 502 produced by a prognostic health monitor for the FFP signature 400 shown in FIG. 12. Initially, the test unit is 100 percent healthy and an RUL estimate 502 equals a model estimate 504. As the frequency degrades after the onset of damage is detected, the test unit is less than 100 percent healthy, the RUL estimate 502 is lower than model estimate 504. As the frequency measurement and test unit continue to degrade the RUL estimate 502 is reduced. Once the measured frequency indicates that the test unit has failed, the RUL estimate 502 equals zero indicating there is no remaining useful life. The straight-line curve 500 of estimates 502 is characteristic of an ideal RUL estimate curve: the estimates decrease linearly regardless of the shape of the FFP signature curve. The y-axis (remaining time) is the RUL estimates and the x-axis (measurement time) is the time of the RUL estimates: both axes use the same unit of measure.

FIG. 14 is a line plot 600 of SoH (state of health) estimates 602 for the FFP signature 400 in FIG. 12 and the RUL estimates 502 in FIG. 13. The SoH estimate 602 is initially 100 percent healthy and is reduced with the onset of detectable damage until indicating a state of health of zero percent at failure and RUL of zero. The y-axis (percent) is the estimated health and the x-axis (time) is the time of the SoH estimate and is the same as the time of the RUL estimate.

There are many different techniques for modeling and estimating RUL and SoH for test units based on a time sequence of measured parameters indicative of degradation of the test unit. Traditionally these parameters included voltages, currents and duty cycle among others. The present invention adds a measurement of resonant frequency of a tuned circuit as a parameter indicative of test unit degradation. The RUL and SoH modeling and estimation techniques process numbers; absolute numbers, changes in numbers and rates of changes in the numbers and are generally agnostic to the specific data parameter. Any of these techniques may be used in conjunction with the measurements of resonant frequency. For example, U.S. application Ser. No. 11/480,791 filed Jul. 3, 2007 by Hofmeister et al entitled “General-purpose adaptive reasoning processor and fault-to-failure progression modeling of a multiplicity of regions of degradation for producing remaining useful life estimations,” may be used to generate SoH and RUL estimates.

The potential value of the present invention is revealed in its application to a SMPS. Power supplies are designed with very large output resistances so they do not ring when the loads they supply are switched. If a prognostic circuit were to rely on the output impedance of the SMPS (e.g. the output impedance of the supply's filter circuit) to cause the circuit to resonate to produce the damped-frequency response, the circuit would have to switch very large voltages to induce very large AC loop currents. These voltages could stress the components of the prognostic circuit. The AC loop currents could be larger than the entire reserve power of the supply, which customers find highly undesirable. By shifting the capacitance and inductance required to make the tuned circuit resonate inside the frequency-sampling circuit and limiting the voltages applied within the circuit, the invention is able to generate the damped-frequency response with limited stress to the components and loading of the power supply, well with the reserve power allocated for the supply.

While several illustrative embodiments of the invention have been shown and described, numerous variations and alternate embodiments will occur to those skilled in the art. Such variations and alternate embodiments are contemplated, and can be made without departing from the spirit and scope of the invention as defined in the appended claims.

We claim:

1. A method of characterizing a health condition of test unit attached to a power supply, said test unit having a characteristic, impedance between an external signal connection and an external reference connection, said method comprising the steps of:
(a) connecting a frequency-sampling circuit between the external signal and reference connections of the test unit, said frequency-sampling circuit comprising an inductor, a capacitor and an output between the inductor and the capacitor, said frequency-sampling circuit configurable in a non-sampling topology and a sampling topology;
(b) establishing a predetermined non-zero DC voltage potential at said output;
(c) switching the frequency-sampling circuit from the non-sampling topology to the sampling topology to simultaneously create a tuned circuit comprising a series connection of the test unit's characteristic impedance and the circuit's inductor and capacitor and change the DC voltage potential at the output causing the tuned circuit to resonate and an AC loop current to flow in the tuned circuit producing a damped-frequency response at the circuit's output, said predetermined non-zero DC voltage potential limiting the change in DC voltage potential at the output and limiting the AC loop current;
(d) generating a resonant-frequency measurement of the damped-frequency response;
(e) switching the frequency-sampling circuit from the sampling topology to the non-sampling topology;
(f) repeating steps (c)-(e) to generate a temporal sequence of resonant-frequency measurements; and
(g) processing the resonant-frequency measurements to generate an indicator of a health condition of the characteristic impedance as a proxy for a health condition of the test unit.

2. The method of claim 1, wherein said predetermined non-zero DC voltage potential is less than 2% of an input voltage potential between the signal and reference connections.

3. The method of claim 1, wherein establishing the predetermined non-zero DC voltage potential at the output comprises connecting a resistive voltage divider between the signal connection and the reference connection at said output.

4. The method of claim 1, wherein establishing the predetermined non-zero DC voltage potential at the output comprises connecting a current-limited DC voltage source at said output.

5. The method of claim 1, wherein the power supply has a reserve power for handling power and load fluctuations, and wherein establishing the predetermined non-zero DC voltage potential limits the change in the DC voltage potential at the output, which limits the AC loop current to be equal to or less than a designed-for percentage of the reserve power.

6. The method of claim 5, wherein the design-for percentage of the reserve power is at most 20%.

7. The method of claim 5, wherein the design-for percentage of the reserve power corresponds to at most 5% of the total power of the power supply

8. The method of claim 1, further comprising switching the frequency-sampling circuit to said non-sampling topology to reduce current flow through the inductor to substantially zero.

9. The method of claim 1, wherein said test unit belongs to a class of units having a specified nominal characteristic impedance, further comprising selecting the inductance and capacitance values of the circuit's inductor and capacitor, respectively, so that the resonant-frequency measurement corresponding to the nominal characteristic impedance lies within a specified frequency range.

10. The method of claim 1, wherein said test unit comprises a second characteristic impedance between a second signal connection and the reference connection, further comprising connecting another said frequency-sampling circuit between the second signal connection and the reference connection and repeating steps (b)-(g).

11. The method of claim 1, wherein processing the resonant-frequency measurements comprises processing a change in the resonant-frequency measurements to generate a state of health (SoH) indicator.

12. The method of claim 1, wherein processing the resonant-frequency measurements comprises processing a rate of change in the resonant-frequency measurements to generate a remaining useful life (RUL) indicator.

13. The method of claim 1, wherein connecting the frequency-sampling circuit between the signal and reference connections comprises connecting one end of the inductor to one of the reference connection or signal connection, connecting a switch between the other end of the inductor and the output and connecting the capacitor between the output and the other one of reference connection or signal connection, and wherein physically switching the frequency-sampling circuit comprises opening the switch to disconnect the inductor in the non-sampling topology and closing the switch to connect the inductor in the sampling topology.

14. The method of claim 1, wherein the test unit is a switch mode power supply with a filter circuit having output impedance.

15. The method of claim 1, wherein connecting the frequency-sampling circuit between the signal and reference connections comprises connecting the capacitor and inductor in series between the signal and reference connections, and wherein electrically switching the frequency-sampling circuit comprises applying a time-varying voltage signal from said power supply through the test unit to electrically switch the frequency-sampling circuit between the non-sampling and sampling topologies.

16. A method of characterizing a health condition of a test unit attached to a power supply, said test unit having a characteristic impedance between an external signal connection and an external reference connection, said method comprising the steps of:
(a) connecting a frequency-sampling circuit between the external signal and reference connections of the test unit, said frequency-sampling circuit comprising an inductor, a capacitor and. an output between the inductor and the capacitor, said frequency-sampling circuit configurable in a non-sampling topology and a sampling topology;
(b) establishing a predetermined non-zero DC voltage potential at said output;
(c) switching the frequency-sampling circuit from the non-sampling topology to the sampling topology to simultaneously create a tuned circuit comprising a series connection of said test unit's characteristic impedance and the circuit's inductor and capacitor and change the DC voltage potential at the output causing the tuned circuit to resonate and an AC loop current to flow in the tuned circuit producing a damped-frequency response at the circuit's output, said predetermined non-zero DC voltage potential limiting the change in DC voltage potential at the output and limiting the AC loop current;
(d) generating a resonant-frequency measurement of the damped-frequency response; and
(e) processing the resonant-frequency measurement to generate an indicator of a health condition of the characteristic impedance as a proxy for a health condition of the test unit.

17. The method of claim 16, wherein said predetermined non-zero DC voltage potential is less than 2% of an input voltage potential between the signal and reference connections.

18. The method of claim 16, wherein the power supply has a reserve power for handling power and load fluctuations, and wherein establishing the predetermined non-zero DC voltage potential limits the change in the DC voltage potential at the output, which limits the AC loop current to be equal to or less than ten percentage of the reserve power.

19. The method of claim 16, wherein said test unit belongs to a class of units having a specified nominal characteristic impedance, further comprising selecting the inductance and capacitance values of the circuit's inductor and capacitor, respectively, so that the resonant-frequency measurement corresponding to the nominal characteristic impedance lies within a specified frequency range.

20. A system for characterizing a health condition of a test unit attached to a power supply, said test unit having a characteristic impedance and an input voltage potential between an external signal connection and an external reference connection, said system comprising:
a frequency-sampling circuit connected between the external signal and reference connections of the test unit, said frequency-sampling circuit comprising an inductor, a capacitor, and an output between the inductor and the capacitor, said frequency-sampling circuit configurable in a non-sampling topology and a sampling topology;
a voltage circuit for establishing a predetermined non-zero DC voltage potential at said output;
means for switching the frequency-sampling circuit from the non-sampling topology to the sampling topology to simultaneously create a tuned circuit comprising a series connection of said test unit's characteristic impedance and the circuit's inductor and capacitor and change the DC voltage potential at the output causing the tuned circuit to resonate and an AC loop current to flow in the tuned circuit producing a damped-frequency response at the circuit's output, said predetermined non-zero DC voltage potential limiting the change in DC voltage potential at the output to be less than 2% of the input voltage potential and limiting the AC loop current;
a frequency-measurement circuit coupled to the output to generate a resonant-frequency measurement of the damped-frequency response; and
a prognostic health monitor that processes the resonant-frequency measurements to generate an indicator of a health condition of the characteristic impedance as a proxy for a health condition of the test unit.

21. The system of claim 20, wherein the frequency-sampling circuit connects one end of the inductor to the reference connection, a switch between the other end of the inductor and the output and the capacitor between the output and the signal connection, said voltage circuit comprises a resistive voltage-divider having a first resistor connected between the signal connection and the output and a second resistor connected between the output and the reference connection, said means for switching the frequency-sampling circuit comprising a controller that issue a signal to open and close the switch.

22. The system of claim 20, wherein the power supply has a reserve power for handling power and load fluctuations, and wherein establishing the predetermined non-zero DC voltage potential limits the change in the DC voltage potential at the output, which limits the AC loop current to be equal to or less than a twenty percent of the reserve power.

23. The system of claim 20, wherein the prognostic health monitor processes a change in the resonant-frequency measurements to generate a state of health (SoH) indicator.

24. The system of claim 20, wherein the prognostic health monitor processes a rate of change in the resonant-frequency measurements to generate a remaining useful life (RUL) indicator.
